(19) United States
(12) Patent Application Publication
(10) Pub. No.: US 2026/0173344 A1
(43) Pub. Date: Jun. 18, 2026

(54) METHOD FOR FABRICATING SEMICONDUCTOR MEMORY DEVICE

(71) Applicant: SAMSUNG ELECTRONICS CO., LTD., Suwon-si (KR)

(72) Inventors: Dong Hyung KIM, Suwon-si (KR); Sang Hoon AHN, Suwon-si (KR); Yong Kwan KIM, Suwon-si (KR); In Woo KIM, Suwon-si (KR); Hui-Jung KIM, Suwon-si (KR); Gyu Soup LEE, Suwon-si (KR); Sang Ho LEE, Suwon-si (KR); Seong Tak CHO, Suwon-si (KR)

(73) Assignee: SAMSUNG ELECTRONICS CO., LTD., Suwon-si (KR)

(21) Appl. No.: 19/213,310

(22) Filed: May 20, 2025

(30) Foreign Application Priority Data
Dec. 18, 2024 (KR) 10-2024-0189661

(51) Int. Cl. H10B 12/00

(52) U.S. Cl. CPC H10B 12/053; H10B 12/315; H10B 12/34

(57) ABSTRACT

A method for fabricating a semiconductor memory device, includes: forming an element separation film that defines active regions on a substrate; forming a trench that intersects the active regions in the substrate; forming a gate insulating film along a profile of the trench; forming a first pre-gate electrode inside the trench; forming a second pre-gate electrode that exposes the gate insulating film, by removing a part of the first pre-gate electrode; forming a sacrificial mask that covers the gate insulating film on the substrate; forming a first gate electrode inside the trench, by removing a part of the second pre-gate electrode using the sacrificial mask; forming a second gate electrode inside the trench, using an area-selective deposition (ASD); and forming a gate capping pattern on the second gate electrode.

### CROSS-REFERENCE TO RELATED APPLICATION

This application is based on and claims priority under 35 U.S.C. § 119 to Korean Patent Application No. 10-2024-0189661, filed on Dec. 18, 2024, in the Korean Intellectual Property Office, the disclosure of which is incorporated by reference herein in its entirety.

### BACKGROUND

The present disclosure relates to a method for fabricating a semiconductor memory device.

As semiconductor elements gradually become highly integrated, individual circuit patterns become finer to implement more semiconductor elements in the same area. That is, as the integration degree of semiconductor elements increases, the design rules of the components of the semiconductor elements decrease.

In highly scaled semiconductor elements, the resistance of the word lines increases as the width of the word lines decreases.

### SUMMARY

Provided is a semiconductor device that may improve element performance and reliability.

Aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the disclosure, a method for fabricating a semiconductor memory device, includes: forming an element separation film that defines active regions on a substrate; forming a trench that intersects the active regions in the substrate; forming a gate insulating film along a profile of the trench; forming a first pre-gate electrode that covers the gate insulating film on the substrate; forming a second pre-gate electrode that exposes the gate insulating film, by removing a part of the first pre-gate electrode; forming a first sacrificial mask on the exposed gate insulating film; forming a first gate electrode by removing a part of the second pre-gate electrode using the first sacrificial mask; forming a third pre-gate electrode on the first gate electrode and the first sacrificial mask; forming a fourth pre-gate electrode that exposes the first sacrificial mask, by removing a part of the third pre-gate electrode; forming a second sacrificial mask on the first sacrificial mask; forming a second gate electrode by removing a part of the fourth pre-gate electrode using the second sacrificial mask; and forming a gate capping pattern on the second gate electrode.

According to an aspect of the disclosure, a method for fabricating a semiconductor memory device, includes: forming an element separation film that defines active regions on a substrate; forming a trench that intersects the active regions in the substrate; forming a gate insulating film along a profile of the trench; forming a first pre-gate electrode inside the trench; forming a second pre-gate electrode that exposes the gate insulating film, by removing a part of the first pre-gate electrode; forming a sacrificial mask that covers the gate insulating film on the substrate; forming a first gate electrode inside the trench, by removing a part of the second pre-gate electrode using the sacrificial mask; forming a second gate electrode inside the trench, using an area-selective deposition (ASD); and forming a gate capping pattern on the second gate electrode.

According to an aspect of the disclosure, a method for fabricating a semiconductor memory device, includes: forming an element separation film that defines active regions on a substrate; forming a trench that intersects the active regions in the substrate; forming a gate insulating film along a profile of the trench; forming a first pre-gate electrode that covers the gate insulating film on the substrate; forming a second pre-gate electrode that exposes the gate insulating film, by removing a part of the first pre-gate electrode; forming a first sacrificial mask on the exposed gate insulating film using an area-selective deposition (ASD) process; forming a first gate electrode by removing a part of the second pre-gate electrode using the first sacrificial mask; forming a third pre-gate electrode on the first gate electrode and the first sacrificial mask; forming a fourth pre-gate electrode that exposes the first sacrificial mask by removing a part of the third pre-gate electrode; forming a second sacrificial mask on the first sacrificial mask, using the ASD process; forming a second gate electrode by removing a part of the fourth pre-gate electrode using the second sacrificial mask; completely or substantially completely removing the first sacrificial mask and the second sacrificial mask; and forming a gate capping pattern on the second gate electrode.

The aspects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail illustrative embodiments thereof with reference to the attached drawings, in which:

FIG. 1 illustrates a semiconductor memory device according to some embodiments of the present disclosure;

FIG. 2 illustrates a region R1 of FIG. 1;

FIG. 3 illustrates a word line and a cell active region of FIG. 2;

FIG. 4 is a plan view showing a region R2 of FIG. 1;

FIGS. 5 to 7 are cross-sectional views taken along A-A, B-B, and C-C of FIG. 4;

FIGS. 8 to 43 illustrate intermediate stages of a method for fabricating a semiconductor memory device according to some embodiments of the present disclosure; and

FIGS. 44 to 47 illustrate a method for fabricating a semiconductor memory device according to another embodiment of the present disclosure.

### DETAILED DESCRIPTION

Terms such as “first” and “second” are used to describe various elements or components in the present disclosure. These elements or components are not limited by these example terms. These terms are used to distinguish a single element or component from other elements or components. Therefore, a first element or component referred to below may be a second element or component within the technical idea of the present disclosure.

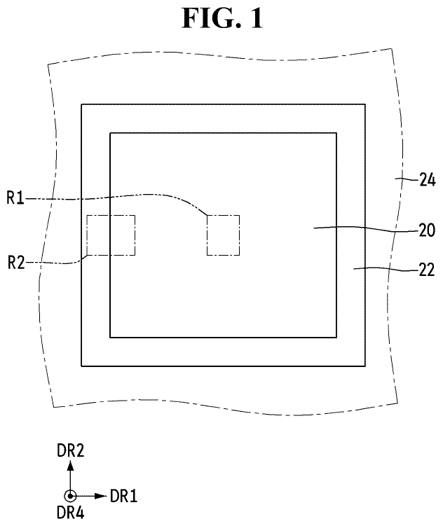

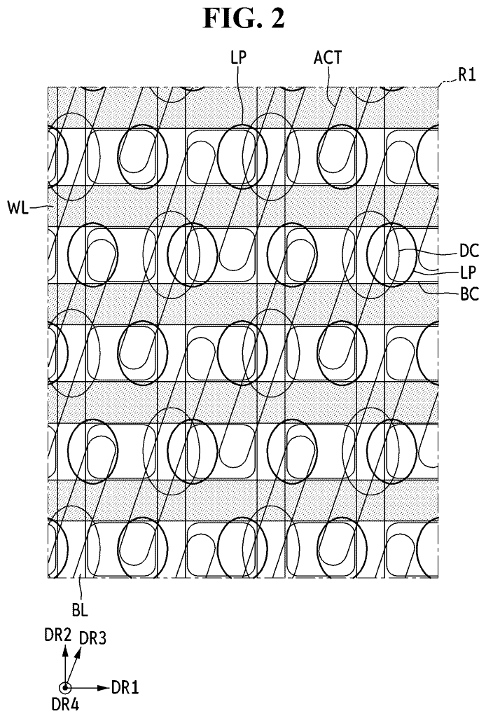

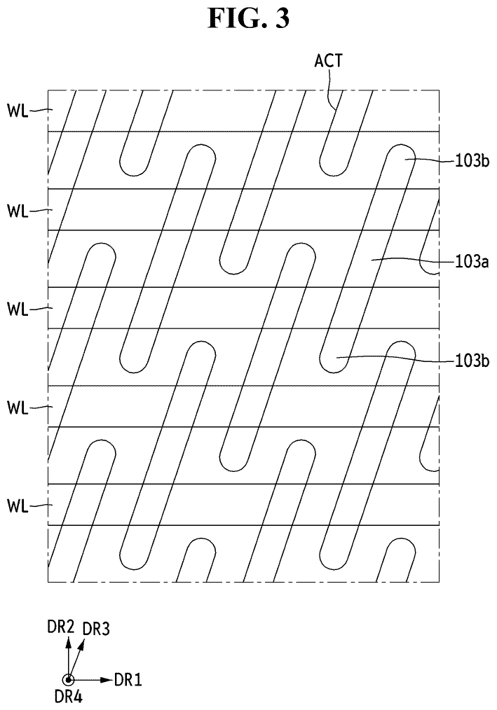

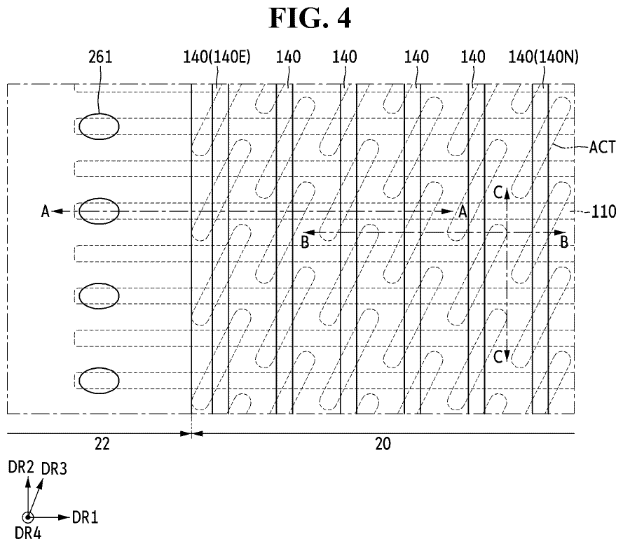

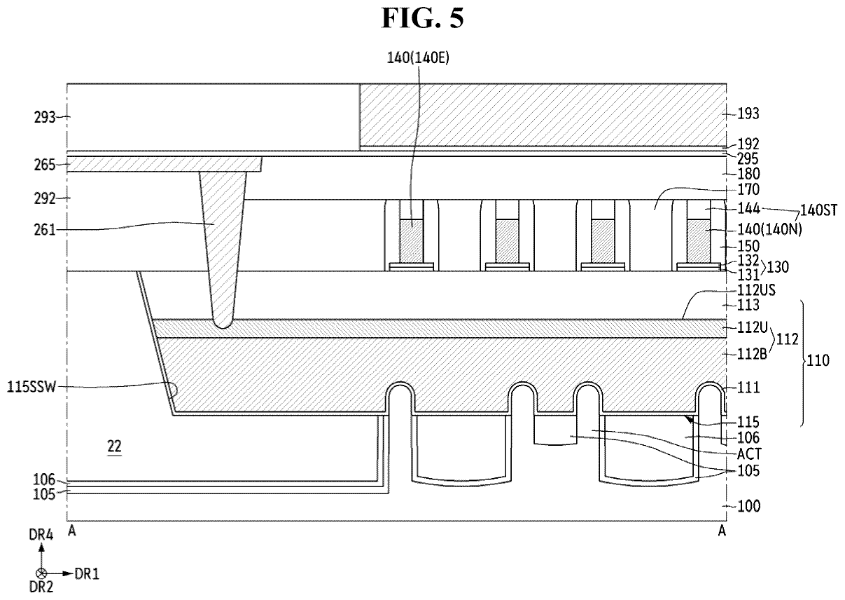

FIG. 1 illustrates a semiconductor memory device according to some embodiments of the present disclosure. FIG. 2 illustrates a region R1 of FIG. 1. FIG. 3 illustrates a word line and a cell active region of FIG. 2. FIG. 4 is a plan view of a region R2 of FIG. 1. FIGS. 5 to 7 are cross-sectional views taken along A-A, B-B, and C-C of FIG. 4. FIG. 4 shows a cell active region ACT, a cell gate structure 110, a cell conductive line 140, and a cell gate plug 261.

Referring to FIGS. 1 to 4, a semiconductor memory device according to some embodiments of the present disclosure includes a cell region 20, a cell region separation film 22, and a peri-region 24.

The cell region separation film 22 may be disposed along the periphery of the cell region 20. The cell region separation film 22 may separate the cell region 20 and the peri-region 24. The cell region 20 may be defined by the cell region separation film 22. The peri-region 24 may be defined around the cell region 20.

The cell region 20 may include a plurality of cell active regions ACT. The cell active region ACT may be defined by a cell element separation film (105 of FIGS. 5 to 7) formed in a substrate (100 of FIGS. 5 to 7). With a decrease in the design rule of the semiconductor memory device, the cell active regions ACT may be disposed in the form of a bar of a diagonal line or an oblique line, as shown, for example, in FIGS. 1 to 4. For example, the cell active region ACT may extend in a third direction DR3.

A plurality of gate electrodes extending in a first direction DR1 across the cell active region ACT may be disposed. The plurality of gate electrodes may extend parallel to each other. The plurality of gate electrodes may be, for example, a plurality of word lines WL. The word lines WL may be disposed at equal intervals. A width of the word lines WL or an interval between the word lines WL may be determined depending on a design rule. The conductive lines included in the cell gate structure 110 may be the word lines WL.

For example, the word line WL may extend up to the cell region separation film 22. A part of the word line WL may overlap the cell region separation film 22 in a fourth direction DR4.

The two word lines WL extending in the first direction DR1 may divide each cell active region ACT into three portions. The cell active region ACT may include a bit line connection region 103a and a storage connection region 103b. The bit line connection region 103a may be located in a center portion of the cell active region ACT, and the storage connection region 103b may be located at an end portion of the cell active region ACT.

A plurality of bit lines BL extending in a second direction DR2 orthogonal to the word line WL may be disposed on the word line WL. The plurality of bit lines BL may extend parallel to each other. The bit lines BL may be disposed at equal intervals. The width of the bit line BL or the interval between the bit lines BL may be determined depending on the design rule.

In an embodiment, the bit line BL may extend up to the cell region separation film 22. A part of the bit line BL may overlap with the cell region separation film 22 in the fourth direction DR4. The fourth direction DR4 may be orthogonal to the first direction DR1, the second direction DR2, and the third direction DR3. The fourth direction DR4 may be a thickness direction of the substrate 100. The first direction DR1 may be orthogonal to the second direction DR2. The third direction DR3 may form any angle with respect to the first direction DR1 and the second direction DR2.

The bit line BL may include a cell conductive line 140. The cell conductive line 140 may include a normal cell conductive line 140N and an edge cell conductive line 140E. For example, the edge cell conductive line 140E may be a cell conductive line disposed at the outermost corner of the cell conductive lines 140.

In an example embodiment, a width of the edge cell conductive line 140E in the first direction DR1 may be identical to a width of the normal cell conductive line 140N in the first direction DR1. The disclosure is not limited to the example embodiment. In another example embodiment, the width of the edge cell conductive line 140E in the first direction DR1 may be greater than the width of the normal cell conductive line 140N in the first direction DR1.

The semiconductor memory device according to some embodiments may include various contact arrangements formed on the cell active region ACT. Various contact arrangements may include, for example, a direct contact DC, a buried contact BC, a landing pad LP, and the like.

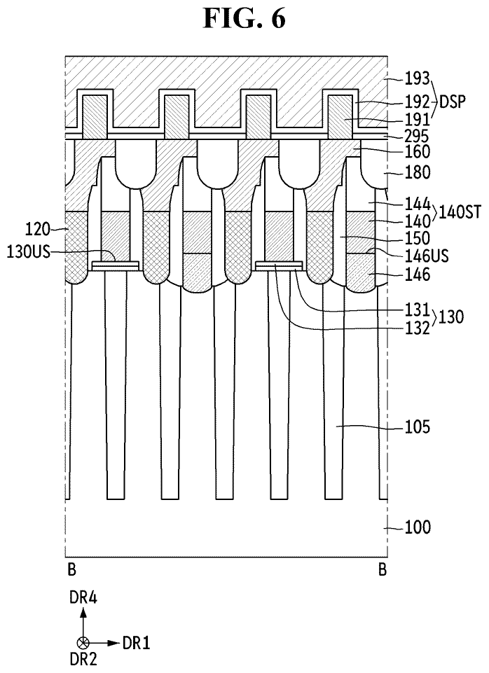

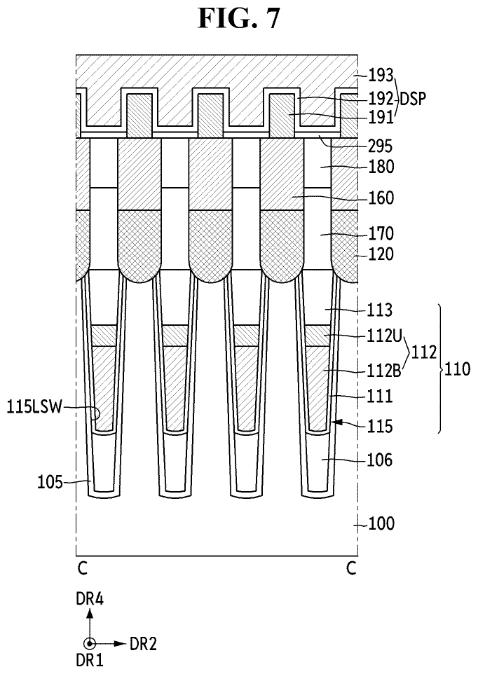

Here, the direct contact DC may be a contact that electrically connects the cell active region ACT to the bit line BL. The buried contact BC may be a contact that connects the cell active region ACT to a lower electrode (191 of FIGS. 6 and 7) of the data storage pattern. A contact area between the buried contact BC and the cell active region ACT may be small due to the placement structure. Therefore, a conductive landing pad LP may be introduced to enlarge the contact area with the cell active region ACT and enlarge the contact area with the lower electrode (191 of FIGS. 6 and 7).

The landing pad LP may be disposed between the cell active region ACT and the buried contact BC or may be disposed between the buried contact BC and the lower electrode (191 of FIGS. 6 and 7). In the semiconductor memory device according to some embodiments, the landing pad LP may be disposed between the buried contact BC and the lower electrode of the data storage pattern. By enlarging the contact area through the introduction of the landing pad LP, the contact resistance between the cell active region ACT and the capacitor lower electrode may decrease.

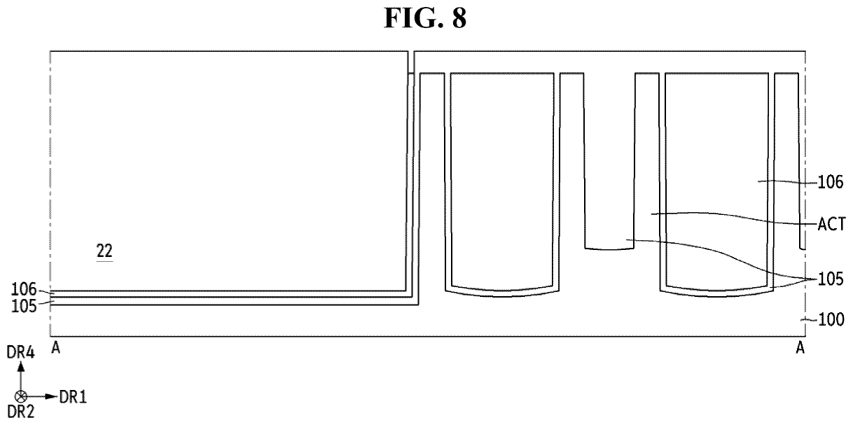

The direct contact DC may be connected to the bit line connection region 103a. The buried contact BC may be connected to the storage connection region 103b. As the buried contact BC is disposed at both end portions of the cell active region ACT, the landing pad LP may be disposed adjacent to both ends of the cell active region ACT to partially overlap the buried contact BC. In other words, the buried contact BC may be formed to overlap the cell active region ACT and the cell element separation film (105 of FIG. 8) between the adjacent word lines WL and between the adjacent bit lines BL.

The word line WL may be formed as a structure buried inside the substrate 100. The word line WL may be disposed across the cell active region ACT between the direct contact DC and the buried contact BC. As shown, for example, in FIGS. 1 to 4, two word lines WL may be disposed to cross one active region ACT. Since the cell active region ACT extends along the third direction DR3, the word line WL may have an angle less than 90 degrees with the cell active region ACT.

The direct contact DC and the buried contact BC may be disposed symmetrically. Therefore, the direct contact DC and the buried contact BC may be disposed on a straight line along the first direction DR1 and the second direction DR2.

In an embodiment, unlike the direct contact DC and the buried contact BC, the landing pads LP may be disposed in a zigzag manner in the second direction DR2 in which the bit line BL extends. Also, the landing pads LP may be disposed to overlap the same side portions of each bit line BL in the first direction DR1 in which the word line WL extends.

For example, each of the landing pads LP of the first line may overlap a left side of the corresponding bit line BL, and each of the landing pads LP of the second line may overlap a right side of the corresponding bit line BL.

A plurality of cell gate plugs 261 may be disposed on the cell gate structure 110. The plurality of cell gate plugs 261 may be connected to the cell gate structure 110. For example, the plurality of cell gate plugs 261 may be connected to the cell gate electrode (112 of FIG. 5) included in the cell gate structure 110.

The cell gate plug 261 may be connected to the cell gate electrode 112 near a longitudinal end of the cell gate structure 110, that is, near a longitudinal end of the word line WL.

Referring to FIGS. 1 to 7, a semiconductor memory device according to some embodiments may include a cell active region ACT, a plurality of cell gate structures 110, a plurality of cell conductive lines 140, a plurality of storage pads 160, a data storage pattern DSP, and a plurality of cell gate plugs 261.

The substrate 100 may include a cell region 20, a cell region separation film 22, and a peri-region 24. The substrate 100 may be a silicon substrate or a silicon-on-insulator (SOI). In contrast, the substrate 100 may include, but is not limited to, silicon germanium, silicon germanium on insulator (SGOI), antimonide indium, lead telluride, indium arsenide, indium phosphide, gallium arsenide or gallium antimonide.

A plurality of cell gate structures 110, a plurality of bit line structures 140ST, a plurality of storage pads 160, and a data storage pattern DSP may be disposed in the cell region 20.

A cell element separation film 105 may be formed in the substrate 100 of the cell region 20. The cell element separation film 105 may have a shallow trench isolation (STI) structure having excellent isolation characteristics. The cell region separation film 22 may have an STI structure like the cell element separation film 105. A cell capping pattern 106 may be disposed between the cell element separation film 105 and the cell region separation film 22 and inside the cell element separation film 105.

An upper surface of the cell capping pattern 106 may come into contact with the lower surface of the cell gate insulating film 111. Specifically, the upper surface of the cell capping pattern 106 may be disposed on the same plane as the lower surface of the cell gate insulating film 111. In other words, the upper surface of the cell capping pattern 106 may come into direct contact with the lower surface of the cell gate insulating film 111.

The cell element separation film 105 may define a cell active region ACT inside the cell region 20. The cell active region ACT defined by the cell element separation film 105 may have a long island shape including a short axis and a long axis, as shown, for example, in FIGS. 2 to 4.

The cell active region ACT may have a diagonal shape to have an angle of less than 90 degrees with respect to the word line WL disposed in the cell element separation film 105. The cell active region ACT may have a diagonal shape to have an angle of less than 90 degrees with respect to the bit line BL formed on the cell element separation film 105.

In other words, the cell active region ACT may have a diagonal shape to have an angle of less than 90 degrees with respect to the cell gate structure 110 disposed in the cell element separation film 105. The cell active region ACT may have a diagonal shape to have an angle of less than 90 degrees with respect to the bit line structure 140ST formed on the cell element separation film 105.

In an example embodiment, a depth from the upper surface of the cell region separation film 22 to the bottom of the cell region separation film 22 may be identical to a depth from the upper surface of the cell region separation film 22 to the bottom of the cell element separation film 105. The disclosure is not limited to the example embodiment. In another embodiment, the depth from the upper surface of the cell region separation film 22 to the bottom of the cell region separation film 22 may be different from the depth from the upper surface of the cell region separation film 22 to the bottom of the cell element separation film 105.

Each of the cell element separation film 105, the cell region separation film 22, and the cell capping pattern 106 may include, for example, but is not limited to, at least one of a silicon oxide film, a silicon nitride film, and a silicon oxynitride film. In FIGS. 5 to 7, as an example embodiment, each of the cell element separation film 105 and the cell region separation film 22 may be formed of a single insulating film. The disclosure is not limited to the example embodiment. In other embodiments, depending on the width of the cell element separation film 105 and the cell region separation film 22, the cell element separation film 105 and the cell region separation film 22 may each be formed of a single insulating film or a plurality of insulating films.

As an example embodiment, FIG. 6 illustrates that the upper surface of the cell element separation film 105 and the upper surface of the substrate 100 are on the same plane. The disclosure is not limited to the above example embodiment.

The plurality of cell gate structures 110 are disposed inside the cell region 20 and the cell region separation film 22. In the cell region 20, each cell gate structure 110 may be formed inside the substrate 100 and the cell element separation film 105. The cell gate structure 110 may be formed across the cell element separation film 105 and the cell active region ACT defined by the cell element separation film 105. A part of the cell gate structure 110 may be disposed inside the cell region separation film 22.

Each cell gate structure 110 may extend in the first direction DR1. Each cell gate structure 110 may be spaced apart in the second direction DR2. The cell gate structure 110 may include a cell gate trench 115, a cell gate insulating film 111, a cell gate electrode 112, and a cell gate capping pattern 113 that are disposed inside the substrate 100 and the cell element isolation layer 105. Here, the cell gate electrode 112 may correspond to the word line WL.

The cell gate trench 115 may be disposed inside the cell region 20 and the cell region separation film 22. The cell gate trench 115 may extend in the first direction DR1. In the cell region 20, the cell gate trench 115 may be disposed inside the substrate 100 and the cell element separation film 105.

The cell gate trench 115 may include a long side wall 115LSW extending in the first direction DR1, and a short side wall 115SSW extending in the second direction DR2. The short side wall 115SSW of the cell gate trench connects the long side walls 115LSW of the cell gate trenches spaced apart in the second direction DR2. Since the longitudinal end of the cell gate structure 110 is disposed in the cell region separation film 22, the short side wall 115SSW of the cell gate trench may be defined by the cell region separation film 22. The cell gate structure 110 may include a first longitudinal end and a second longitudinal end that are spaced apart in the first direction DR1.

The bottom surface of the cell gate trench 115 may be curved. The cell gate trench 115 may be relatively deep in the cell element separation film 105 and relatively shallow in the cell active regions ACT. That is, the depth of the cell gate trench 115 in the cell element separation film 105 may be greater than the depth of the cell gate trench 115 in the cell active region ACT.

The cell gate insulating film 111 may extend along the long side wall 115LSW of the cell gate trench, the short side wall 115SSW of the cell gate trench, and the bottom surface of the cell gate trench 115. The cell gate insulating film 111 may extend along a profile of at least a part of the cell gate trench 115. The cell gate insulating film 111 may include, for example, at least one of silicon oxide, silicon nitride, silicon oxynitride or a high dielectric constant material having a higher dielectric constant than silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations of these materials.

The cell gate electrode 112 may be disposed on the cell gate insulating film 111. The cell gate electrode 112 may fill a part of the cell gate trench 115.

The cell gate electrode 112 may include a lower cell gate electrode 112B and an upper cell gate electrode 112U that are stacked in a fourth direction DR4. The lower cell gate electrode 112B and the upper cell gate electrode 112U may each extend in the first direction DR1. The upper cell gate electrode 112U may include an upper surface 112US of the cell gate electrode. Each of the lower cell gate electrode 112B and the upper cell gate electrode 112U may be made up of, but is not limited to, a single film. As another example, the lower cell gate electrode 112B and the upper cell gate electrode 112U may include a double film.

Each of the lower cell gate electrode 112B and the upper cell gate electrode 112U may include a conductive material, for example, at least one of a conductive metal nitride, a conductive metal silicon nitride, a metal carbonitride, a conductive metal silicide, a conductive metal oxide, a two-dimensional material, and a metal.

Each of the lower cell gate electrode 112B and the upper cell gate electrode 112U may include, but is not limited to, at least one of titanium nitride (TiN), tungsten (W), and molybdenum (Mo). In the semiconductor memory device according to some embodiments, at least one of the lower cell gate electrode 112B and the upper cell gate electrode 112U may have a single conductive film structure. Each of the lower cell gate electrode 112B and the upper cell gate electrode 112U may have a single film structure. For example, each of the lower cell gate electrode 112B and the upper cell gate electrode 112U may have a single conductive film structure.

For example, some of the bit lines BL included in the semiconductor memory device may be dummy bit lines that are not used in the operation of actual memory cells. That is, some of the memory cells included in the semiconductor memory device may be dummy memory cells. The rest of the memory cells included in the semiconductor memory device may be normal memory cells that operate as actual memory cells.

For example, the edge cell conductive line 140E may be included in the dummy bit line. As one example, the normal cell conductive line 140N may not be used as a dummy bit line. As another example, some of the normal cell conductive lines 140N adjacent to the edge cell conductive line 140E may be included in the dummy bit line.

The cell gate capping pattern 113 may be disposed on the cell gate electrode 112. The cell gate capping pattern 113 may extend along the upper surface 112US of the cell gate electrode. The cell gate capping pattern 113 may fill the cell gate trench 115 that remains after the cell gate electrode 112 and the cell gate insulating film 111 are formed. In an example embodiment, the cell gate insulating film 111 may extend along the side wall of the cell gate capping pattern 113. The disclosure is not limited to the above example embodiment.

The cell gate capping pattern 113 includes an upper surface of the cell gate structure 110. The upper surface of the cell gate capping pattern 113 may be the upper surface of the cell gate structure 110. The cell gate capping pattern 113 may be formed of an insulating material. The cell gate capping pattern 113 may include, for example, at least one of silicon nitride, silicon oxynitride, silicon oxide, silicon carbon nitride, silicon oxycarbonitride, and combinations of these materials.

In an embodiment, an impurity-doped region may be formed on at least one side of the cell gate structure 110. The impurity-doped region may be a source/drain region of a transistor. The impurity-doped region may be formed in the storage connection region 103b and the bit line connection region 103a of FIG. 3.

The bit line structure 140ST may include a cell conductive line 140 and a cell line capping film 144. The bit line structure 140ST may include a normal cell conductive line 140N and a cell line capping film 144. The bit line structure 140ST disposed at the outermost corner of the cell region 20 may include an edge cell conductive line 140E. The cell conductive line 140 may be disposed on the substrate 100 and the cell element separation film 105 on which the cell gate structure 110 is disposed.

The cell conductive line 140 may extend in the second direction DR2. The cell conductive line 140 may intersect the cell element separation film 105 and the cell active region ACT defined by the cell element separation film 105. Here, the cell conductive line 140 may correspond to the bit line BL.

The cell conductive line 140 may include, for example, at least one of a semiconductor material doped with impurities, a conductive silicide compound, a conductive metal nitride, a two-dimensional material (2D material), and a metal. In the semiconductor memory device according to some embodiments, the two-dimensional material may be a metallic material and/or a semiconductor material. The two-dimensional material (2D material) may include a two-dimensional allotrope or a two-dimensional compound, and may include, for example, but is not limited to, at least one of graphene, molybdenum disulfide (MoS₂), molybdenum diselenide (MoSe₂), tungsten diselenide (WSe₂), and tungsten disulfide (WS₂). That is, the above-mentioned two-dimensional materials are merely listed as examples, and the two-dimensional materials that may be included in the semiconductor memory device of the present disclosure are not limited to the above-mentioned materials.

In an example embodiment, the cell conductive line 140 may be a single film. The disclosure is not limited to the example embodiment. In another example embodiment, the cell conductive line 140 may include a plurality of conductive films in which the conductive materials are stacked.

The cell line capping film 144 may be disposed on the cell conductive line 140. The cell line capping film 144 may extend in the second direction DR2 along the upper surface of the cell conductive line 140. The cell line capping film 144 may include, for example, at least one of a silicon nitride film, a silicon oxynitride, a silicon carbon nitride, and a silicon oxycarbonitride. In the semiconductor memory device according to some embodiments, the cell line capping film 144 may include a silicon nitride film. In an example embodiment, the cell line capping film 144 is a single film. The disclosure is not limited to the example embodiment.

A bit line contact 146 may be formed between the cell conductive line 140 and the substrate 100. That is, the cell conductive line 140 may be disposed on the bit line contact 146. For example, the bit line contact 146 may be disposed at a point on which the cell conductive line 140 intersects the central portion of the cell active region ACT having a long island shape. The bit line contact 146 may be disposed between the bit line connection region 103a of the cell active region ACT and the cell conductive line 140. The bit line contact 146 may be connected to the bit line connection region 103a.

The plurality of bit line contacts 146 may be disposed along the second direction DR2. Each cell conductive line 140 may be disposed on the plurality of bit line contacts 146, and extend along the second direction DR2.

The bit line contact 146 may electrically connect the cell conductive line 140 and the substrate 100. Here, the bit line contact 146 may correspond to a direct contact DC. The bit line contact 146 may include, for example, at least one of a semiconductor material doped with impurities, a conductive silicide compound, a conductive metal nitride, and a metal.

In FIG. 6, the thickness of the cell conductive line 140 in the region (that overlaps the upper surface 146US of the bit line contact) may be smaller than the thickness of the cell conductive line 140 in the region that does not overlap the upper surface 146US of the bit line contact. In an embodiment, the thickness of the cell conductive line 140 in the region (that overlaps the upper surface 146US of the bit line contact) may be identical to the thickness of the cell conductive line 140 in the region that does not overlap the upper surface 146US of the bit line contact.

The cell insulating film 130 may be disposed on the substrate 100 and the cell element separation film 105. More specifically, the cell insulating film 130 may be disposed on the substrate 100 and the cell element separation film 105 on which the bit line contact 146 is not formed. The cell insulating film 130 may be disposed between the substrate 100 and the cell conductive line 140, and may be disposed between the cell element separation film 105 and the cell conductive line 140. In the semiconductor memory device according to some embodiments, the upper surface 146US of the bit line contact may be higher than the upper surface 130US of the cell insulating film on the basis of the upper surface of the substrate 100.

In an embodiment, the cell insulating film 130 may be a single film. In an embodiment, the cell insulating film 130 may be a multi-layer film including a first cell insulating film 131 and a second cell insulating film 132. For example, the first cell insulating film 131 may include a silicon oxide film, and the second cell insulating film 132 may include a silicon nitride film. The disclosure is not limited to the above example embodiments. In an embodiment, the cell insulating film 130 may include three or more insulating films.

A cell line spacer 150 may be disposed on the side walls of the cell conductive line 140 and the side walls of the cell line capping film 144. In a portion of the cell conductive line 140 in which the bit line contact 146 is formed, the cell line spacer 150 may be formed on the substrate 100 and the cell element separation film 105. The cell line spacer 150 may be disposed on the side walls of the cell conductive line 140, the side walls of the cell line capping film 144, and the side walls of the bit line contact 146.

In the remaining portion of the cell conductive line 140 in which the bit line contact 146 is not formed, the cell line spacer 150 may be disposed on the cell insulating film 130. The cell line spacer 150 may be disposed on the side walls of the cell conductive line 140 and the side walls of the cell line capping film 144.

In an example embodiment, the cell line spacer 150 is a single film. The disclosure is not limited to the above example embodiment. In an embodiment, the cell line spacer 150 may have a multi-layer film structure. The cell line spacer 150 may include, for example, but is not limited to, one of a silicon oxide film, a silicon nitride film, a silicon oxynitride film, a silicon oxycarbonitride film, air, and a combination of these films.

A fence pattern 170 may be disposed on the substrate 100 and the cell element separation film 105. The fence pattern 170 may be disposed to overlap the cell gate structure 110 formed in the substrate 100 and the cell element separation film 105. The fence pattern 170 may be disposed on the cell gate capping pattern 113.

The fence pattern 170 may be disposed between the bit line structures 140ST extending in the second direction DR2. The fence pattern 170 may include, for example, at least one of silicon oxide, silicon nitride, silicon oxynitride, and combinations of these materials.

The plurality of storage contacts 120 may be disposed between the cell conductive lines 140 adjacent to each other in the first direction DR1. The storage contact 120 may be disposed between the fence patterns 170 adjacent to each other in the second direction DR2. The storage contact 120 may overlap the substrate 100 and the cell element separation film 105 between adjacent cell conductive lines 140 in the fourth direction DR4. The storage contact 120 may be connected to the storage connection region 103b of the cell active region ACT. Here, the storage contact 120 may correspond to the buried contact BC.

The storage contact 120 may include, for example, at least one of a semiconductor material doped with impurities, a conductive silicide compound, a conductive metal nitride, and a metal.

A storage pad 160 may be disposed on each storage contact 120. The storage pad 160 may be electrically connected to the storage contact 120. The storage pad 160 may be connected to the storage connection region 103b of the cell active region ACT. Here, the storage pad 160 may correspond to the landing pad LP.

The storage pad 160 may overlap a part of the upper surface of the cell conductive line 140. The storage pad 160 may include, for example, at least one of a semiconductor material doped with impurities, a conductive silicide compound, a conductive metal nitride, a conductive metal carbide, and a metal.

The pad separation insulating film 180 may be disposed on the storage pad 160 and the cell conductive line 140. For example, the pad separation insulating film 180 may be disposed on the cell line capping film 144. The pad separation insulating film 180 may define the storage pad 160 that forms a plurality of isolation regions. The pad separation insulating film 180 may not cover the upper surface of the storage pad 160. The pad separation insulating film 180 may fill the pad separation recess. The pad separation recess may separate adjacent storage pads 160.

The pad separation insulating film 180 includes an insulating material and may electrically separate the storage pads 160 from each other. For example, the pad separation insulating film 180 may include at least one of, for example, but is not limited to, a silicon oxide film, a silicon nitride film, a silicon oxynitride film, a silicon oxycarbonitride film, and a silicon carbon nitride film.

A lower peri-interlayer insulating film 292 may be disposed on the substrate 100 of the peri-region 24. The lower peri-interlayer insulating film 292 may be disposed on the cell region separation film 22.

The lower peri-interlayer insulating film 292 may include an oxide-based insulating material. For example, the lower peri-interlayer insulating film 292 may include silicon oxide.

An upper etching stop film 295 may be disposed on the upper surface of the storage pad 160 and the upper surface of the pad separation insulating film 180. The upper etching stop film 295 may be disposed on the lower peri-interlayer insulating film 292. The upper etching stop film 295 may include at least one of, for example, silicon nitride, silicon carbon nitride, silicon oxycarbonitride, silicon oxycarbide, and silicon boron nitride.

The data storage pattern DSP may be disposed on the storage pad 160. The data storage pattern DSP is connected to the storage pad 160. A part of the data storage pattern DSP may be disposed inside the upper etching stop film 295.

As an example, the data storage pattern DSP may be a capacitor. The data storage pattern DSP includes a lower electrode 191, a capacitor dielectric film 192, and an upper electrode 193. For example, the upper electrode 193 may be a plate upper electrode having a plate shape.

The lower electrode 191 may be disposed on the storage pad 160. The lower electrode 191 may have, for example, a pillar shape. The capacitor dielectric film 192 is disposed on the lower electrode 191. The capacitor dielectric film 192 may be formed along the profile of the lower electrode 191. The upper electrode 193 is disposed on the capacitor dielectric film 192. The upper electrode 193 may wrap the outer wall of the lower electrode 191. In an example embodiment, the upper electrode 193 may be a single film. The disclosure is not limited to the above example embodiment. In an embodiment, the lower electrode 191 may have a cylindrical shape with one side open.

Each of the lower electrode 191 and the upper electrode 193 may include, but is not limited to, a doped semiconductor material, a conductive metal nitride (e.g., titanium nitride, tantalum nitride, niobium nitride, tungsten nitride or the like), a metal (e.g., ruthenium, iridium, titanium, tantalum or the like), and a conductive metal oxide (e.g., iridium oxide, niobium oxide or the like).

The capacitor dielectric film 192 may include, but is not limited to, for example, one of silicon oxide, silicon nitride, silicon oxynitride, a high dielectric constant material, and a combination of these materials. The capacitor dielectric film 192 may include at least one of a ferroelectric material, an antiferroelectric material, and a paraelectric material. The capacitor dielectric film 192 may include, for example, one of the ferroelectric material, the antiferroelectric material, the paraelectric material, a combination of the ferroelectric and antiferroelectric materials, a combination of the ferroelectric and paraelectric materials, a combination of the paraelectric and antiferroelectric materials, and a combination of the ferroelectric material, the antiferroelectric material and the paraelectric material.

In the semiconductor memory device according to some embodiments, the capacitor dielectric film 192 may include a stacked film structure in which zirconium oxide, aluminum oxide, and zirconium oxide are sequentially stacked. In the semiconductor memory device according to some embodiments, the capacitor dielectric film 192 may include a dielectric film including hafnium (Hf).

In contrast, the data storage patterns DSP may be variable resistance patterns that may be switched between two resistance states by electrical pulses applied to the memory element. For example, the data storage patterns DSP may include a phase-change material, perovskite compounds, transition metal oxide, magnetic materials, ferromagnetic materials or antiferromagnetic materials whose crystal state changes according to the amount of current.

The upper peri-interlayer insulating film 293 may be disposed on the upper etching stop film 295. The upper peri-interlayer insulating film 293 may cover the side wall of the upper electrode 193. The upper peri-interlayer insulating film 293 may include, but is not limited to, at least one of a silicon oxide film, a silicon nitride film, a silicon oxynitride film, a silicon oxycarbonitride film, and a silicon carbon nitride film.

A peri-connection line 265 may be disposed on the cell region separation film 22. The peri-connection line 265 may extend up to the peri-region 24. For example, the peri-connection line 265 may be connected to the gate electrode and/or source/drain region of a peri-transistor disposed in the peri-region 24. The peri-connection line 265 may connect the cell gate electrode 112 and the peri-transistor disposed in the peri-region 24.

A plurality of cell gate plugs 261 may be disposed on each cell gate electrode 112. Each cell gate plug 261 may be connected to the corresponding cell gate electrode 112. For example, the cell gate plug 261 is electrically connected to the cell gate electrode 112.

The cell gate plug 261 is disposed between the cell gate electrode 112 and the peri-connection line 265. The cell gate plug 261 connects the cell gate electrode 112 and the peri-connection line 265.

Each of the peri-connection line 265 and the cell gate plug 261 may include at least one of a semiconductor material doped with impurities, a conductive silicide compound, a conductive metal nitride, a conductive metal carbide, and a metal. In an example embodiment, the peri-connection line 265 and the cell gate plug 261 are different films. The disclosure is not limited to the above example embodiment.

FIGS. 8 to 43 illustrate intermediate stages of a method for fabricating a semiconductor memory device according to some embodiments of the present disclosure. FIGS. 8 to 44 are cross-sectional views taken along lines A-A and C-C of FIG. 4.

Referring to FIG. 8, the cell region separation film 22, the cell element separation film 105, and the cell capping pattern 106 may be formed in the substrate 100.

The cell region separation film 22 may be formed to define a cell region (20 of FIG. 1) and a peri-region (24 of FIG. 1). The cell element separation film 105 and the cell capping pattern 106 may define the cell active region ACT.

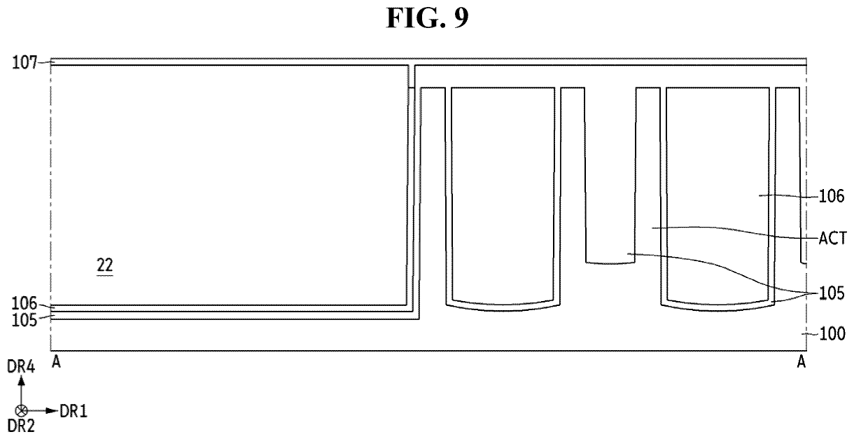

Next, referring to FIG. 9, a gate insulating film 107 may be formed on the cell region separation film 22. The gate insulating film 107 may be formed to cover the cell region separation film 22, the cell element separation film 105, and the cell capping pattern 106.

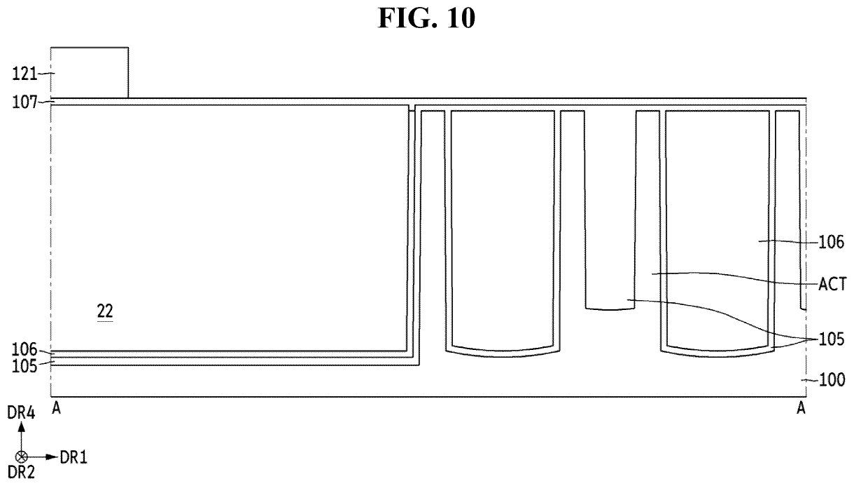

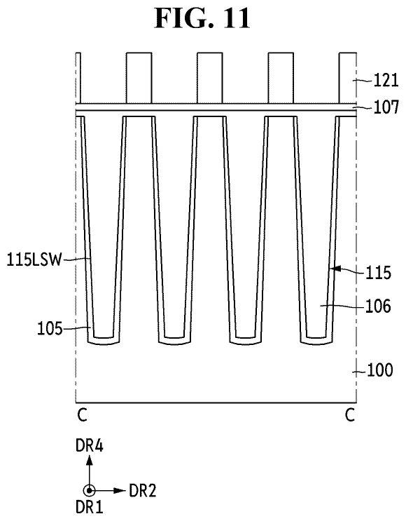

Referring to FIGS. 10 and 11, a mask layer 121 may be formed on the gate insulating film 107. The mask layer 121 may be formed to cover a part of the gate insulating film 107. For example, referring to FIG. 11, the mask layer 121 may be formed to cover a part of the gate insulating film 107 and not to cover the other part of the gate insulating film 107.

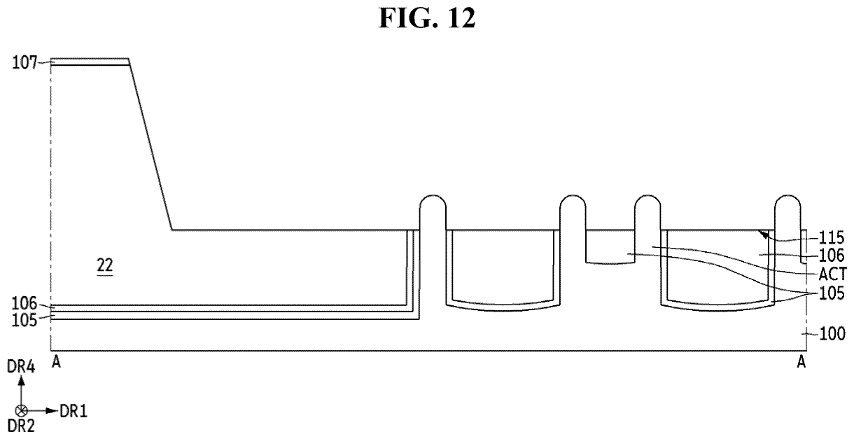

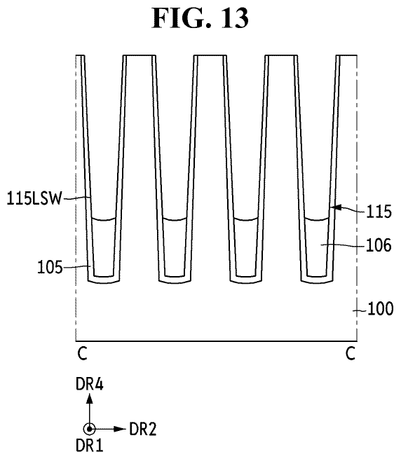

Referring to FIGS. 12 and 13, the cell gate trench 115 may be formed in the cell region 20 and the cell region separation film 22. The cell gate trench 115 may extend long in the first direction DR1.

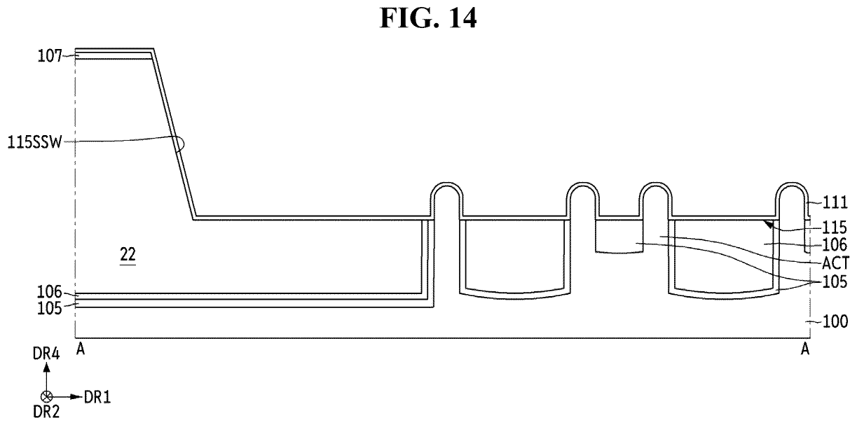

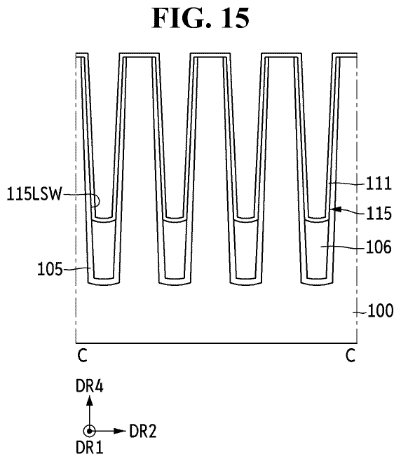

Referring to FIGS. 14 and 15, the cell gate insulating film 111 may be formed along the profile of the cell gate trench 115. The cell gate insulating film 111 may be formed along the long side wall 115LSW of the cell gate trench, the short side wall 115SSW of the cell gate trench, and the bottom surface of the cell gate trench 115. The cell gate insulating film 111 may be formed along the upper surface of the substrate 100 and the upper surface of the cell region separation film 22.

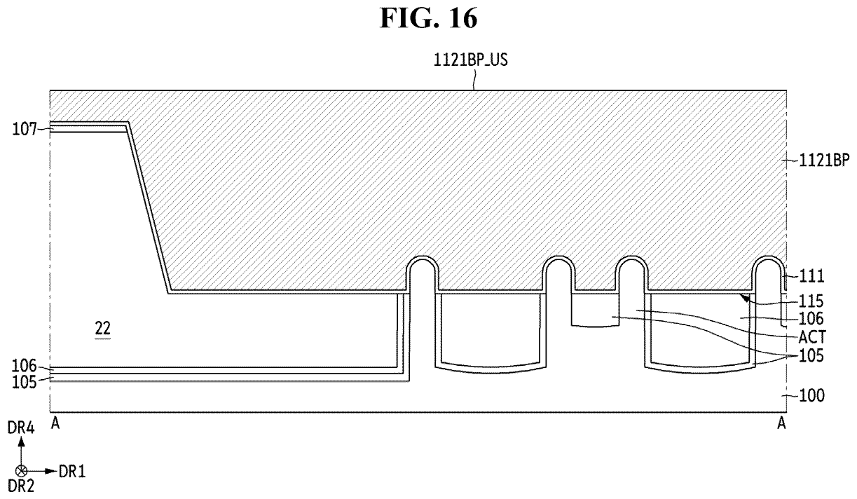

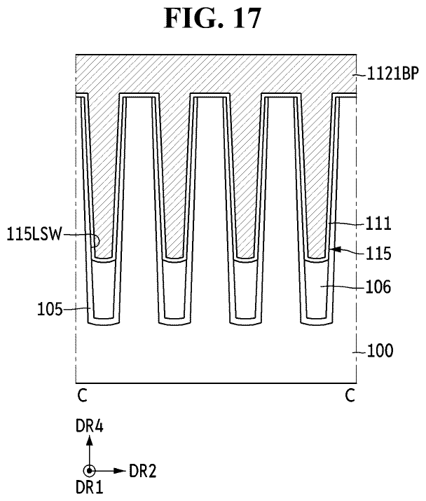

Next, referring to FIGS. 16 and 17, a first pre-lower cell gate electrode 1121BP may be formed on the substrate 100. Specifically, the first pre-lower cell gate electrode 1121BP may be formed to completely cover the cell gate insulating film 111.

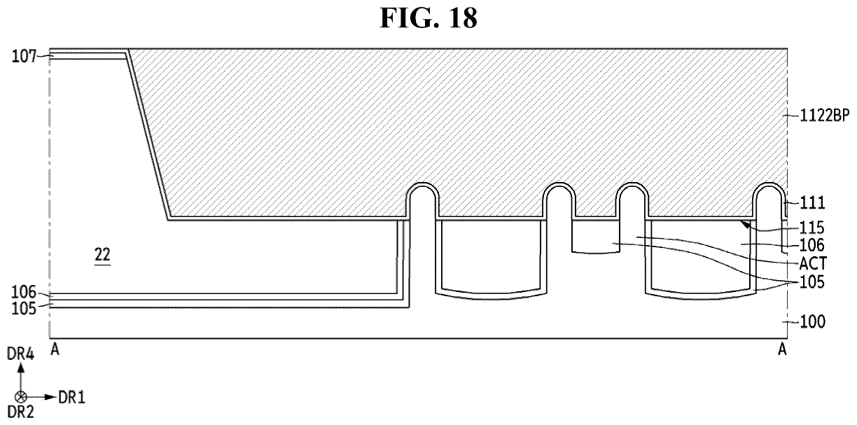

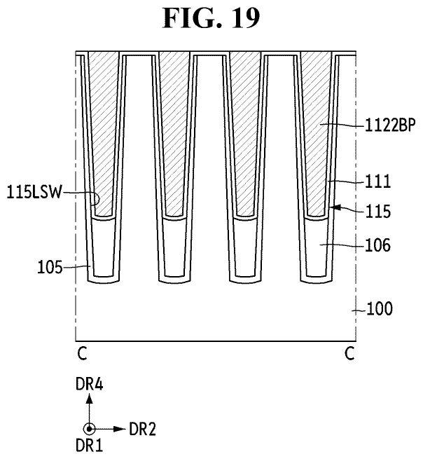

Referring to FIGS. 18 and 19, a part of the first pre-lower cell gate electrode (e.g., 1121BP of FIGS. 16 and 17) may be removed to form a second pre-lower cell gate electrode 1122BP. A part of the first pre-lower cell gate electrode 1121BP may be removed to expose a part of the cell gate insulating film 111.

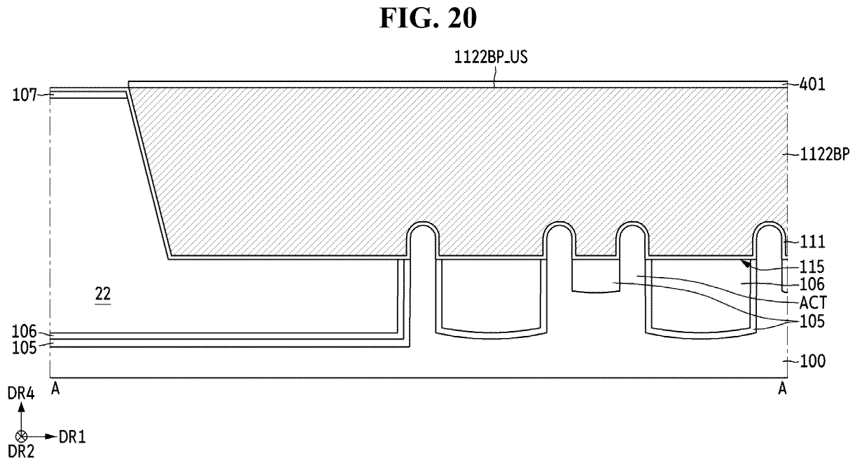

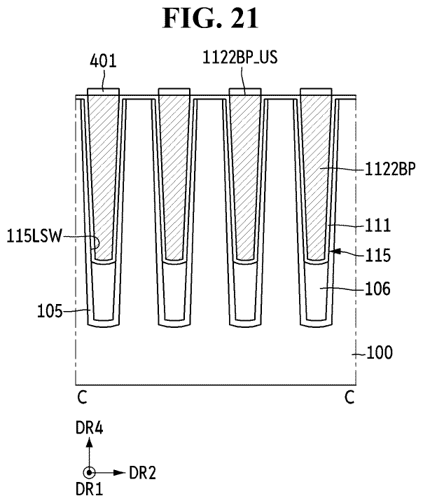

Referring to FIGS. 20 and 21, a first self-assemble monolayer (SAM) 401 may be formed on an upper surface 1122BP_US of the second pre-lower gate electrode. The first self-assemble monolayer 401 may protect the second pre-lower cell gate electrode 1122BP.

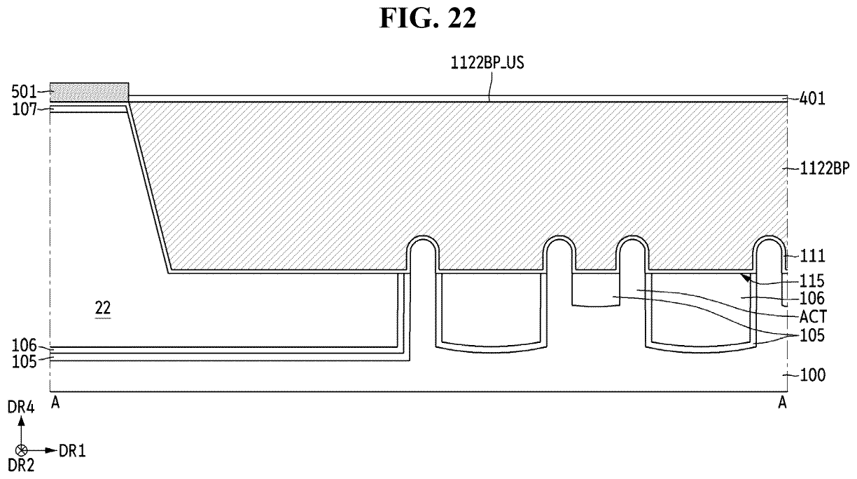

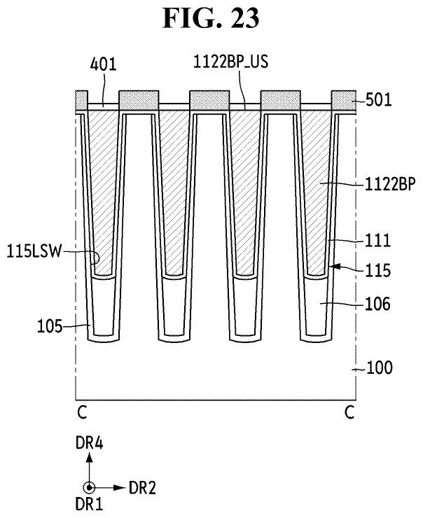

Referring to FIGS. 22 and 23, a first sacrificial mask 501 may be formed in a portion in which the first self-assemble monolayer 401 is not formed. In other words, the first sacrificial mask 501 may be formed on the exposed cell gate insulating film 111. The first sacrificial mask 501 is not formed on the second pre-lower cell gate electrode 1122BP. The first sacrificial mask 501 may be formed by an area-selective deposition (ASD).

The first sacrificial mask 501 may include, but is not limited to, an oxide. As another example, the first sacrificial mask 501 may include silicon nitride.

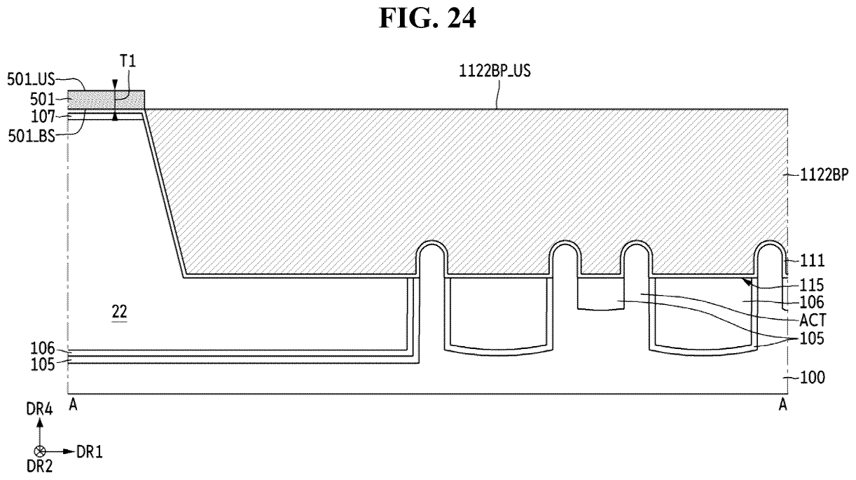

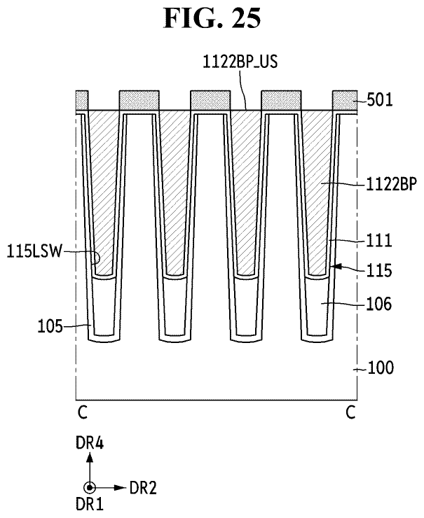

Next, referring to FIGS. 24 and 25, the first self-assemble monolayer (e.g., 401 of FIGS. 22 and 23) may be removed. For example, the first self-assemble monolayer 401 may be removed by an ashing process. The first self-assemble monolayer 401 is removed, and the upper surface 1122BP_US of the second pre-lower cell gate electrode may be exposed.

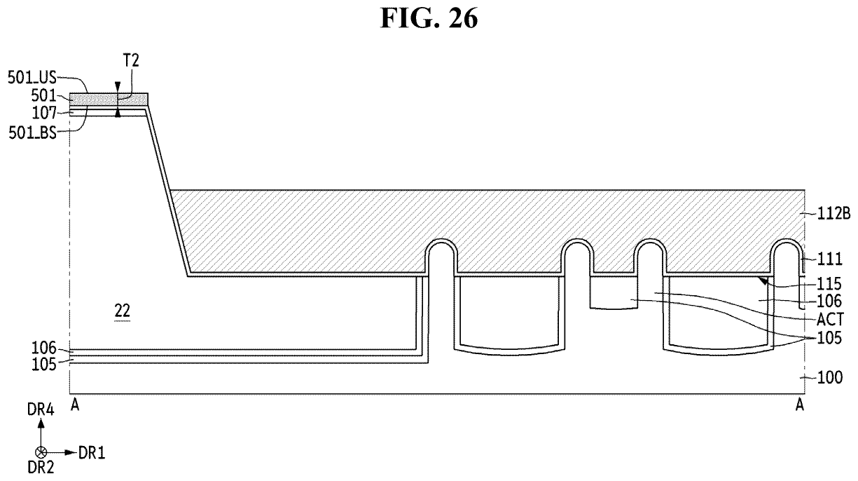

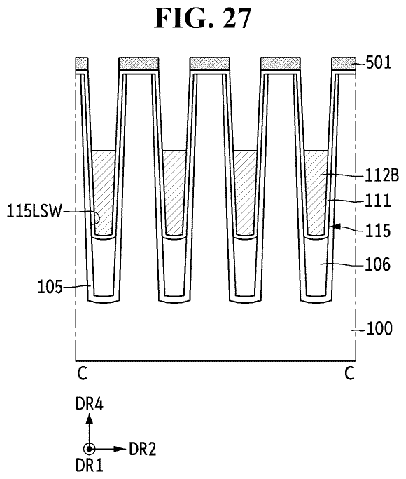

Referring to FIGS. 26 and 27, a part of the second pre-lower cell gate electrode (e.g., 1122BP of FIGS. 24 and 25) may be removed to form the lower cell gate electrode 112B. For example, a part of the second pre-lower cell gate electrode 1122BP may be removed by a chemical mechanical polishing process (CMP).

A width (e.g., T1 of FIG. 24) in the fourth direction DR4 from the lower surface 501_BS of the first sacrificial mask to the upper surface 501_US of the first sacrificial mask may decrease via a chemical mechanical polishing process. In other words, a width (e.g., T2 of FIG. 26) in the fourth direction DR4 from the lower surface 501_BS of the first sacrificial mask to the upper surface 501_US of the first sacrificial mask may decrease compared to before the chemical mechanical polishing process. In the process of removing a part of the second pre-lower cell gate electrode 1122BP, the width of the first sacrificial mask in the fourth direction DR4 may decrease.

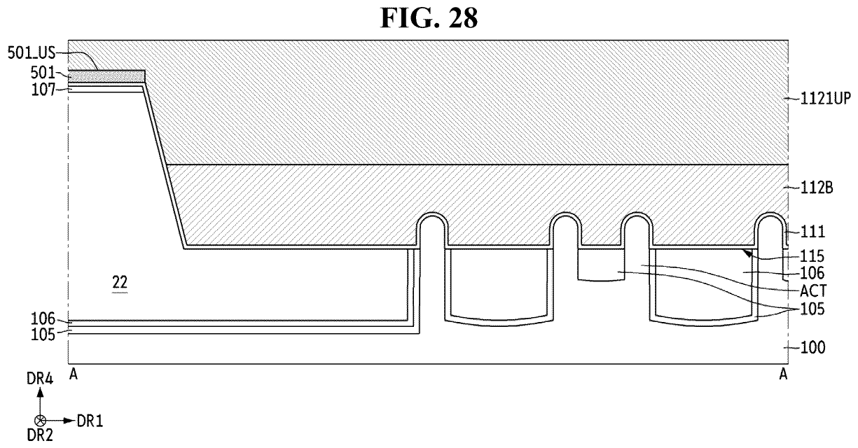

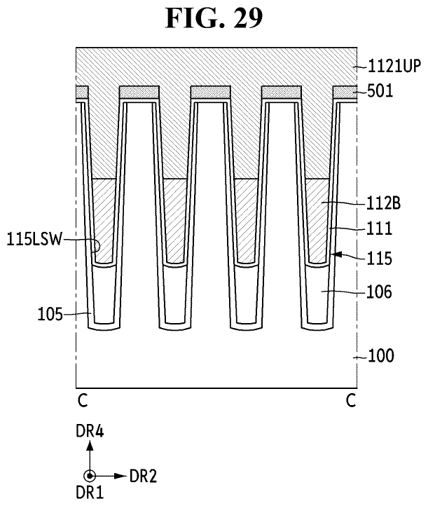

Referring to FIGS. 28 and 29, a first pre-upper cell gate electrode 1121UP may be formed on the lower cell gate electrode 112B. The first pre-upper cell gate electrode 1121UP may be formed to cover the entire lower cell gate electrode 112B. The first pre-upper cell gate electrode 1121UP may be formed to cover the entire upper surface 501_US of the first sacrificial mask. The first pre-upper cell gate electrode 1121UP may be formed to cover at least a part of the cell gate insulating film 111. In other words, the first pre-upper cell gate electrode 1121UP may be formed to cover the exposed cell gate insulating film 111.

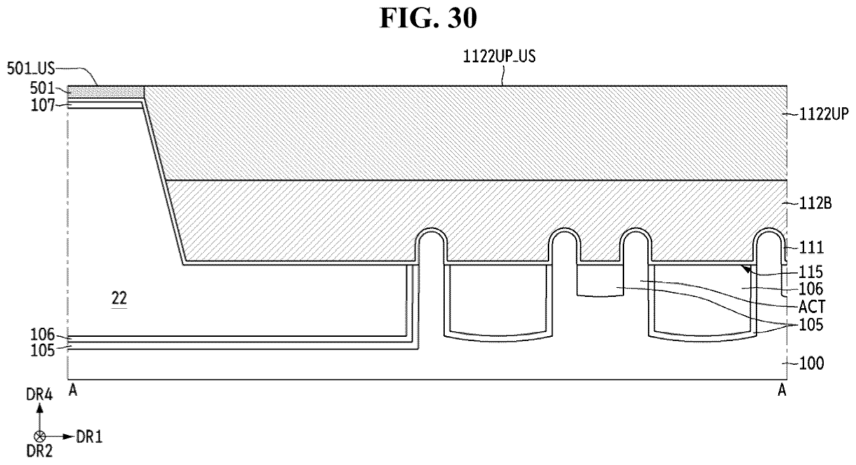

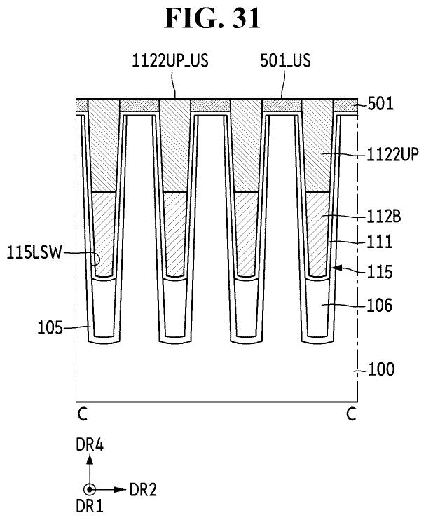

Referring to FIGS. 30 and 31, a part of the first pre-upper cell gate electrode (e.g., 1121UP of FIGS. 28 and 29) may be removed to form a second pre-upper cell gate electrode 1122UP. For example, a part of the first pre-upper cell gate electrode 1121UP may be removed by a chemical mechanical polishing process (CMP). An upper surface 1122UP_US of the second pre-upper cell gate electrode may be disposed on the same plane as an upper surface 501_US of the first sacrificial mask.

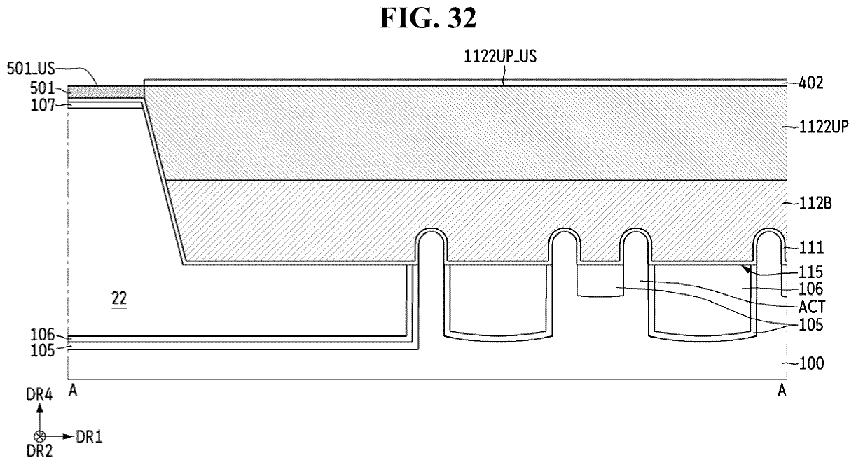

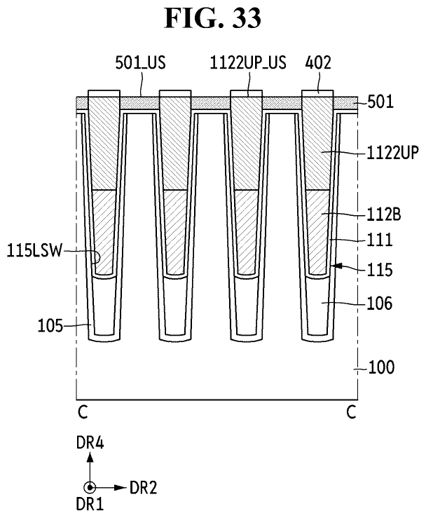

Referring to FIGS. 32 and 33, a second self-assemble monolayer may be formed on the upper surface 1122UP_US of the second pre-upper cell gate electrode. The second self-assemble monolayer 402 may protect the second pre-upper cell gate electrode 1122UP.

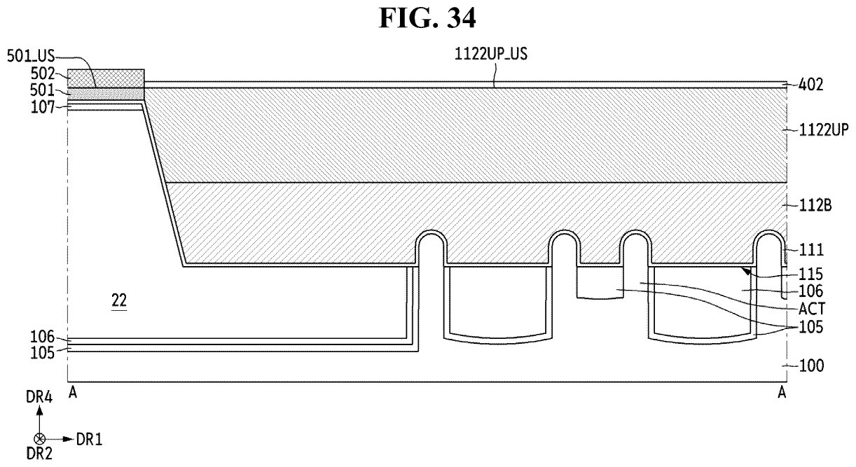

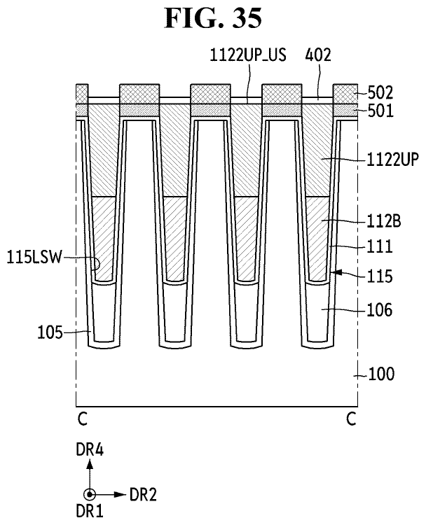

Referring to FIGS. 34 and 35, a second sacrificial mask 502 may be formed in a portion in which the second self-assemble monolayer 402 is not formed. In other words, the second sacrificial mask 502 may be formed on the exposed upper surface 501_US of the first sacrificial mask. The second sacrificial mask 502 is not formed on the second pre-upper cell gate electrode 1122UP. The second sacrificial mask 502 is not formed on the lower cell gate electrode 112B. The second sacrificial mask 502 may include, but is not limited to, an oxide. The second sacrificial mask 502 may be formed by an area-selective deposition (ASD).

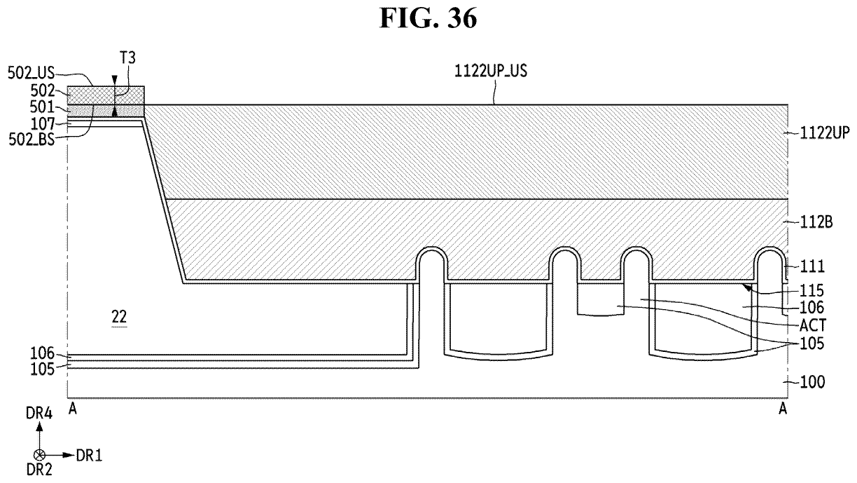

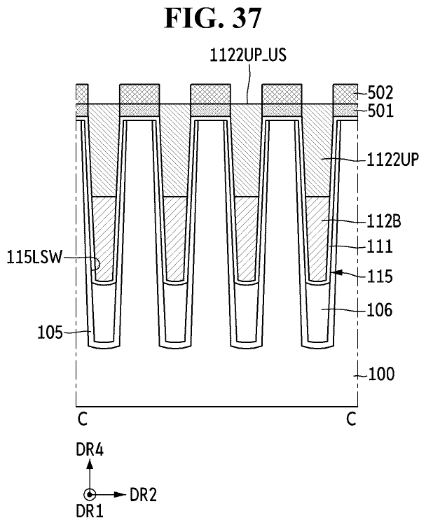

Next, referring to FIGS. 36 and 37, the second self-assemble monolayer (e.g., 402 of FIGS. 34 and 35) may be removed. For example, the second self-assemble monolayer 402 may be removed by an ashing process. The second self-assemble monolayer 402 is removed, and the upper surface 1122UP_US of the second pre-upper cell gate electrode may be exposed.

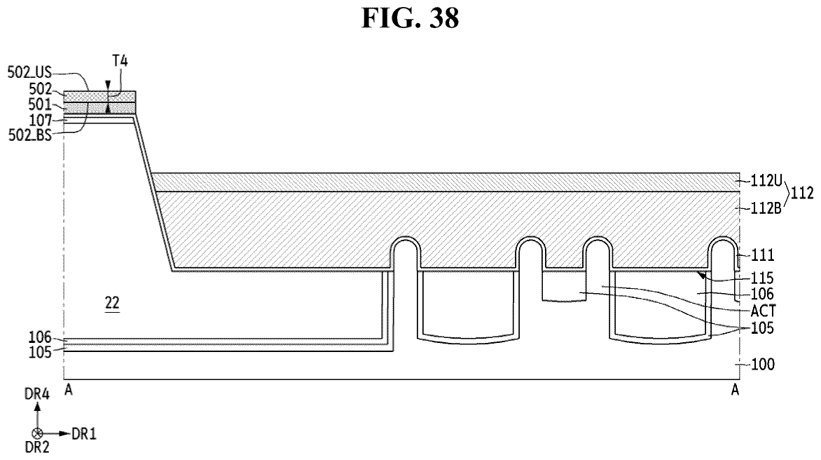

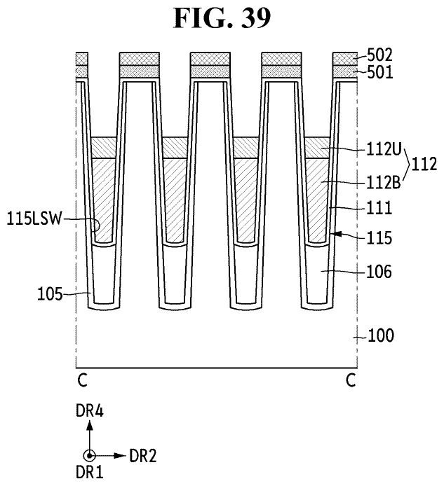

Referring to FIGS. 38 and 39, a part of the second pre-upper cell gate electrode (e.g., 1122UP of FIGS. 26 and 37) is removed, and the upper cell gate electrode 112U may be formed. That is to say, the cell gate electrode 112 including the lower cell gate electrode 112B and the upper cell gate electrode 112U may be formed. For example, a part of the second pre-upper cell gate electrode 1122UP may be removed by a chemical mechanical polishing process (CMP).

A width (e.g., T3 of FIG. 36) in the fourth direction DR4 from the lower surface 502_BS of the second sacrificial mask to the upper surface 502_US of the second sacrificial mask may decrease via the chemical mechanical polishing process. In other words, a width T4 in the fourth direction DR4 from the lower surface 502_BS of the second sacrificial mask to the upper surface 502_US of the second sacrificial mask may decrease compared to before the chemical mechanical polishing process. In the process of removing a part of the second pre-lower cell gate electrode 1122BP, the width of the second sacrificial mask in the fourth direction DR4 may decrease.

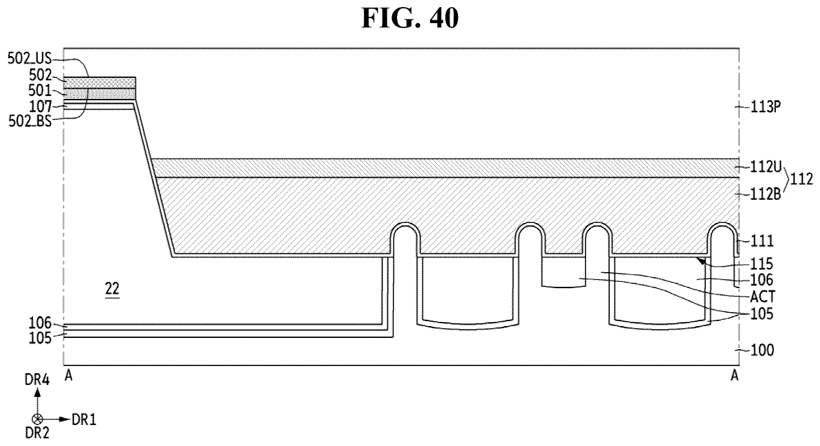

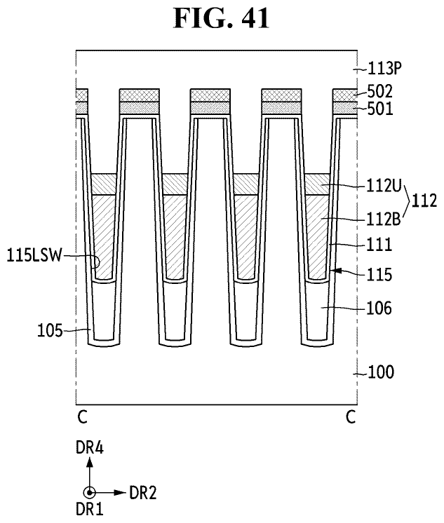

Referring to FIGS. 40 and 41, a pre-cell gate capping pattern 113P may be formed on the upper cell gate electrode 112U and the second sacrificial mask 502. The pre-cell gate capping pattern 113P may be formed to cover the entire cell gate electrode 112. The pre-cell gate capping pattern 113P may be formed to cover the entire second sacrificial mask 502. The pre-cell gate capping pattern 113P may be formed to cover at least a part of the cell gate insulating film 111. In other words, the pre-cell gate capping pattern 113P may be formed to cover the exposed cell gate insulating film 111.

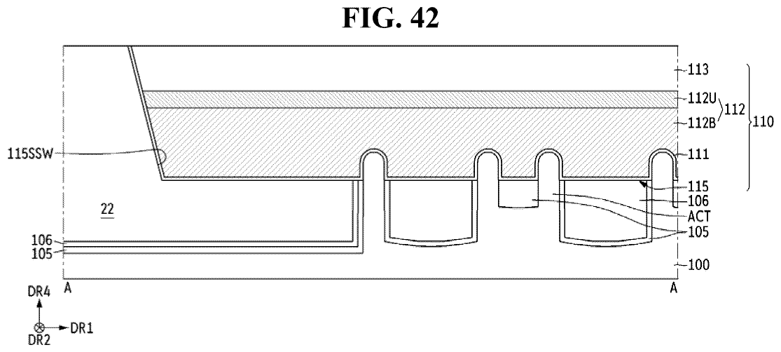

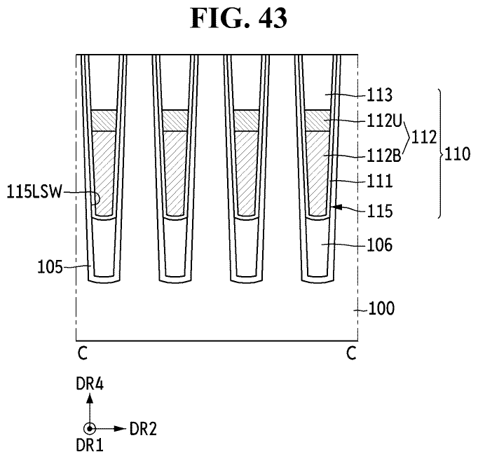

Referring to FIGS. 42 and 43, a part of the pre-cell gate capping pattern (e.g., 113P of FIGS. 40 and 41) may be removed to form the cell gate capping pattern 113. In other words, the cell gate structure 110 including the cell gate trench 115, the cell gate insulating film 111, the cell gate electrode 112, and the cell gate capping pattern 113 may be formed.

The first sacrificial mask 501 and the second sacrificial mask 502 may be completely removed. In an example embodiment, the first sacrificial mask 501 and the second sacrificial mask 502 are removed simultaneously. The disclosure is not limited to the above example embodiment. As another example, the first sacrificial mask 501 may be sequentially removed after the second sacrificial mask 502 is removed.

Each of the first sacrificial mask 501 and the second sacrificial mask 502 may be removed by an etching process. For example, each of the first sacrificial mask 501 and the second sacrificial mask 502 may be removed by a wet etching process. As another example, each of the first sacrificial mask 501 and the second sacrificial mask 502 may be removed by sequentially performing a primary wet etching process, a strip process, and a secondary wet etching process.

Next, referring to FIGS. 5 and 7, the bit line structure 140ST may be formed on the cell gate structure 110. The data storage pattern DSP may be formed on the bit line structure 140ST.

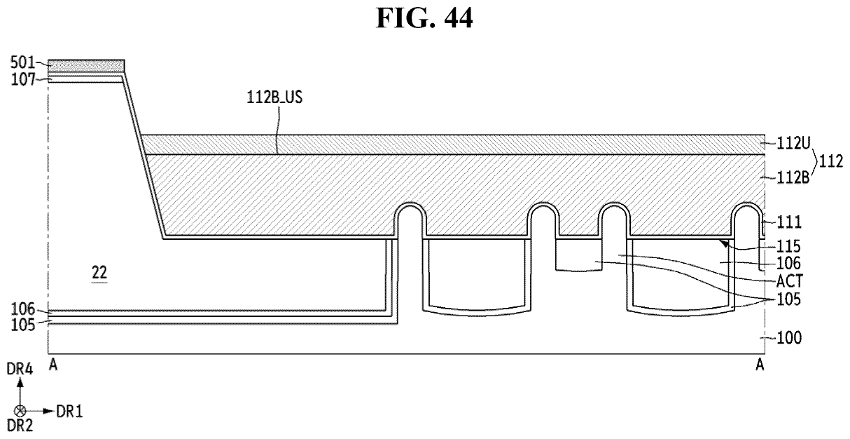

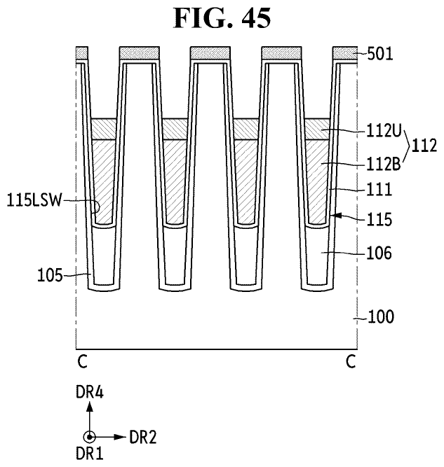

FIGS. 44 to 47 illustrate a method for fabricating a semiconductor memory device according to another embodiment of the present disclosure. FIGS. 44 and 45 are intermediate diagrams continuing from FIGS. 26 and 27, respectively.

Referring to FIGS. 44 and 45, the upper cell gate electrode 112U may be formed on the lower cell gate electrode 112B. The upper cell gate electrode 112U may not be formed on the first sacrificial mask 501, but may be formed on the lower cell gate electrode 112B. The upper cell gate electrode 112U may be formed by the area-selective deposition (ASD).

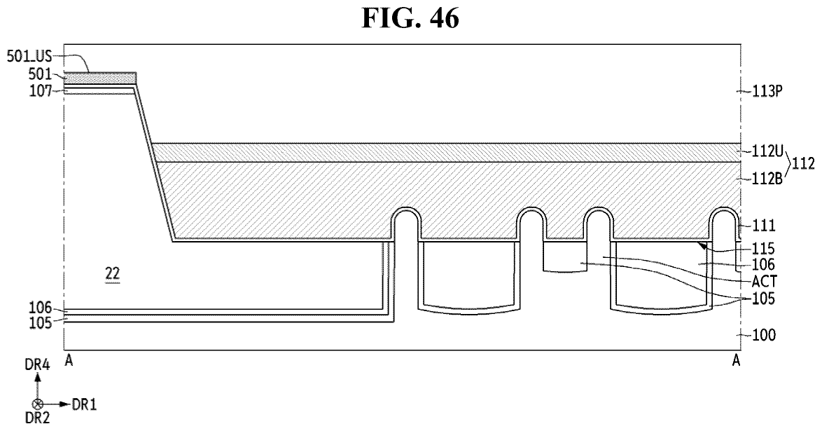

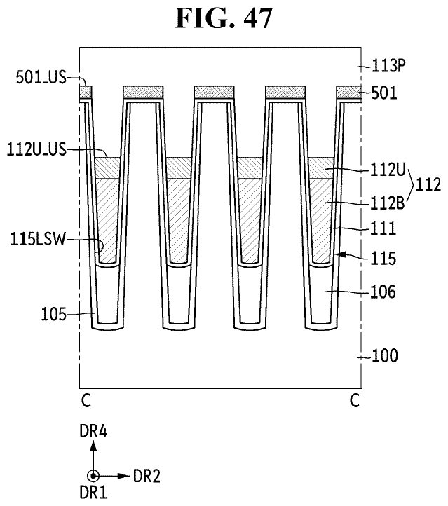

Referring to FIGS. 46 and 47, a pre-cell gate capping pattern 113P may be formed on the upper cell gate electrode 112U and the first sacrificial mask 501. The pre-cell gate capping pattern 113P may be formed to cover the entire cell gate electrode 112. The pre-cell gate capping pattern 113P may be formed to cover the entire first sacrificial mask 501. The pre-cell gate capping pattern 113P may be formed to cover at least a part of the cell gate insulating film 111. In other words, the pre-cell gate capping pattern 113P may be formed to cover the exposed cell gate insulating film 111.

Next, referring to FIGS. 5 and 7, a part of the pre-cell gate capping pattern (e.g., 113P of FIGS. 46 and 47) may be removed to form the cell gate capping pattern 113. In other words, the cell gate structure 110 including the cell gate trench 115, the cell gate insulating film 111, the cell gate electrode 112, and the cell gate capping pattern 113 may be formed.

The first sacrificial mask 501 and the second sacrificial mask 502 may be completely removed. Each of the first sacrificial mask 501 and the second sacrificial mask 502 may be removed by an etching process. For example, each of the first sacrificial mask 501 and the second sacrificial mask 502 may be removed by a wet etching process. As another example, each of the first sacrificial mask 501 and the second sacrificial mask 502 may be removed by sequentially performing a first wet etching process, a strip process, and a second wet etching process.

The bit line structure 140ST may be formed on the cell gate structure 110. The data storage pattern DSP may be formed on the bit line structure 140ST.

In concluding the detailed description, those skilled in the art will appreciate that many variations and modifications may be made to the embodiments without substantially departing from the principles of the present disclosure. Therefore, the disclosed embodiments of the disclosure are used in a generic and descriptive sense and not for purposes of limitation.

What is claimed is:

1. A method for fabricating a semiconductor memory device, the method comprising:
forming an element separation film that defines active regions on a substrate;
forming a trench that intersects the active regions in the substrate;
forming a gate insulating film along a profile of the trench;
forming a first pre-gate electrode that covers the gate insulating film on the substrate;
forming a second pre-gate electrode that exposes the gate insulating film, by removing a part of the first pre-gate electrode;
forming a first sacrificial mask on the exposed gate insulating film;
forming a first gate electrode by removing a part of the second pre-gate electrode using the first sacrificial mask;
forming a third pre-gate electrode on the first gate electrode and the first sacrificial mask;
forming a fourth pre-gate electrode that exposes the first sacrificial mask, by removing a part of the third pre-gate electrode;
forming a second sacrificial mask on the first sacrificial mask;
forming a second gate electrode by removing a part of the fourth pre-gate electrode using the second sacrificial mask; and
forming a gate capping pattern on the second gate electrode.

2. The method of claim 1, wherein the first sacrificial mask includes at least one of an oxide and a silicon nitride.

3. The method of claim 1, wherein the second sacrificial mask includes an oxide.

4. The method of claim 1, further comprising:
forming a first self-assemble monolayer on the first pre-gate electrode, after exposing the gate insulating film; and
forming a second self-assemble monolayer on the fourth pre-gate electrode after exposing the first sacrificial mask.

5. The method of claim 4, further comprising:
removing the first self-assemble monolayer after forming the first sacrificial mask; and
removing the second self-assemble monolayer after forming the second sacrificial mask.

6. The method of claim 1, wherein the forming the first sacrificial mask comprises forming the first sacrificial mask by an area-selective deposition (ASD), and
wherein the forming the second sacrificial mask comprises forming the second sacrificial mask by the ASD.

7. The method of claim 1, wherein the forming the gate capping pattern on the second gate electrode comprises completely or substantially completely removing the first sacrificial mask and the second sacrificial mask.

8. The method for fabricating the semiconductor memory device of claim 1, wherein the forming the gate capping pattern comprises forming a pre-gate capping pattern on the second gate electrode and removing a part of the pre-gate capping pattern.

9. The method of claim 1, wherein the first gate electrode includes a single film.

10. A method for fabricating a semiconductor memory device, the method comprising:
forming an element separation film that defines active regions on a substrate;
forming a trench that intersects the active regions in the substrate;
forming a gate insulating film along a profile of the trench;
forming a first pre-gate electrode inside the trench;
forming a second pre-gate electrode that exposes the gate insulating film, by removing a part of the first pre-gate electrode;
forming a sacrificial mask that covers the gate insulating film on the substrate;
forming a first gate electrode inside the trench, by removing a part of the second pre-gate electrode using the sacrificial mask;
forming a second gate electrode inside the trench, using an area-selective deposition (ASD); and
forming a gate capping pattern on the second gate electrode.

11. The method of claim 10, further comprising completely or substantially completely removing the sacrificial mask after forming the second gate electrode.

12. The method of claim 11, wherein the sacrificial mask includes an oxide.

13. The method of claim 12, wherein the removing the sacrificial mask comprises removing the sacrificial mask by a wet etching process.

14. The method of claim 11, wherein the sacrificial mask includes a silicon nitride.

15. The method of claim 14, wherein the removing the sacrificial mask comprises the removing the sacrificial mask by a primary wet etching process, a strip process, and a secondary wet etching process, which are performed in sequence.

16. The method of claim 10, wherein the forming the sacrificial mask comprises the forming the sacrificial mask by the ASD.

17. The method of claim 10, further comprising forming a first self-assemble monolayer on the second pre-gate electrode after exposing the gate insulating film.

18. The method of claim 10, wherein the first gate electrode includes a monolayer.

19. The method of claim 10, wherein the forming the gate capping pattern comprises:
forming a pre-gate capping pattern on the second gate electrode, and
removing at least a part of the pre-gate capping pattern.

20. A method for fabricating a semiconductor memory device, the method comprising:
forming an element separation film that defines active regions on a substrate;
forming a trench that intersects the active regions in the substrate;
forming a gate insulating film along a profile of the trench;
forming a first pre-gate electrode that covers the gate insulating film on the substrate;
forming a second pre-gate electrode that exposes the gate insulating film, by removing a part of the first pre-gate electrode;
forming a first sacrificial mask on the exposed gate insulating film using an area-selective deposition (ASD) process;
forming a first gate electrode by removing a part of the second pre-gate electrode using the first sacrificial mask;
forming a third pre-gate electrode on the first gate electrode and the first sacrificial mask;
forming a fourth pre-gate electrode that exposes the first sacrificial mask by removing a part of the third pre-gate electrode;
forming a second sacrificial mask on the first sacrificial mask, using the ASD process;
forming a second gate electrode by removing a part of the fourth pre-gate electrode using the second sacrificial mask;
completely or substantially completely removing the first sacrificial mask and the second sacrificial mask; and
forming a gate capping pattern on the second gate electrode.
